(19) United States
(12) Patent Application Publication
(10) Pub. No.: US 2014/0175159 A1
(43) Pub. Date: Jun. 26, 2014

(54) Thermocompression Bonding Method And Apparatus For Mounting Semiconductor Chips On A Substrate

(71) Applicant: Besi Switzerland AG, Cham (CH)

(72) Inventor: Hannes Kostner, Absam (AT)

(73) Assignee: Besi Switzerland AG, Cham (CH)

(21) Appl. No.: 14/137,811

(22) Filed: Dec. 20, 2013

(30) Foreign Application Priority Data
Dec. 21, 2012 (CH) 2915/12

(51) Int. Cl. H01L 23/00; H01L 21/66

(52) U.S. Cl. CPC H01L 24/81; H01L 22/12
USPC 228/102; 228/180.1; 228/103; 228/4.1

(57) ABSTRACT

A thermocompression bonding method for mounting semiconductor chips on a substrate comprises:
picking up the semiconductor chip with a chip gripper displaceably mounted on a TC bonding head;
positioning of the chip gripper above the assigned substrate location;
lowering the TC bonding head up to a position in which the chip gripper is deflected by a predetermined distance relative to the TC bonding head;
heating of the semiconductor chip to a temperature above the melting point of the solder, so that the deflection of the chip gripper becomes zero again;
waiting until the temperature of the semiconductor chip has fallen to a value beneath the melting temperature of the solder, and
lifting of the TC bonding head.

### PRIORITY CLAIM

Applicant hereby claims priority under 35 U.S.C. §119 from Swiss patent application no. 2915/12 filed Dec. 21, 2012, the disclosure of which is herein incorporated by reference.

### FIELD OF THE INVENTION

The invention relates to a thermocompression bonding method and an apparatus for mounting semiconductor chips on a substrate.

### BACKGROUND OF THE INVENTION

Thermocompression bonding methods for mounting semiconductor chips are known for example from U.S. Pat. No. 6,131,795, U.S. Pat. No. 7,296,727, WO 2011152479 and WO 2012002300.

### SUMMARY OF THE INVENTION

It is the object of the invention to improve such a thermocompression bonding method.

The invention concerns a thermocompression bonding method for mounting semiconductor chips on a surface of a substrate, in which one semiconductor chip after the other is taken up by a chip gripper and is mounted on the substrate, wherein a TC bonding head is displaceable by means of a drive in a Z direction extending perpendicularly to the surface of the substrate, the chip gripper is displaceably mounted on the TC bonding head in the Z direction, and a force transmitter fixed to the TC bonding head is configured to press an extension of the chip gripper in the direction of a stop of the TC bonding head, and wherein the chip gripper comprises a heater, wherein the following steps are performed in order to produce solid soldered connections in form of soldering points between a semiconductor chip and the substrate:
picking up the semiconductor chip with the chip gripper;
positioning of the chip gripper above the assigned substrate location;
lowering the TC bonding head by means of the drive to a Z position in which the chip gripper is deflected by a predetermined distance DS relative to the TC bonding head, so that the extension of the chip gripper does not rest on the stop of the TC bonding head;
heating up of the semiconductor chip by means of the heater;
terminating the heat-up of the semiconductor chip once the semiconductor chip has reached a temperature above the melting temperature of the solder of the soldering points, so that the soldering points melt and the extension of the chip gripper comes to lie on the stop of the TC bonding head;
waiting until the temperature of the semiconductor chip has fallen to a value beneath the melting temperature of the solder, and
lifting of the TC bonding head.

The thermocompression bonding method may further comprise actively cooling of the chip gripper during said waiting.

The thermocompression bonding method may further comprise:
from the start of the heating-up of the semiconductor chip until the point in time at which the temperature of the chip gripper has reached a predetermined value that lies beneath the melting temperature of the solder measuring the actual deflection D of the chip gripper relative to the TC bonding head and using the measured deflection D for a closed-loop control of the Z position of the TC bonding head in such a way that the chip gripper remains deflected by the predetermined distance D_{S}.

The step of lowering of the TC bonding head may comprise:
determining a distance D_{TS} by which a support, on which the substrate rests, and the TC bonding head are displaced relative to each other by the force exerted by the chip gripper, and reducing the distance D_{S} by the distance D_{TS}.

The step of lowering of the TC bonding head may alternatively comprise:
determining a distance D_{TS} by which a support, on which the substrate rests, and the TC bonding head are displaced relative to each other by the force exerted by the chip gripper, and lifting of the TC bonding head by the distance D_{TS} as soon as the solder starts melting.

An apparatus for mounting semiconductor chips on a surface of a substrate according to the invention comprises:
a TC bonding head which is displaceably mounted in a Z direction extending perpendicularly to the surface of the substrate and comprises a stop;
a chip gripper which is displaceably mounted in the Z direction on the TC bonding head and which comprises an extension;
a force transmitter which is fixed to the TC bonding head and which presses the extension of the chip gripper in the Z direction against the stop of the TC bonding head;
a drive for moving the TC bonding head in the Z direction;
a first position measuring element for the detection of the Z position of the TC bonding head;
a second position measuring element for detecting a deflection of the chip gripper relative to the TC bonding head; and
a closed-loop control device for controlling the drive, wherein the control device is set up to control the drive selectively on the basis of a position signal which is supplied by the first position measuring element or the second position measuring element.

### BRIEF DESCRIPTION OF THE DRAWING FIGURES

The accompanying drawings, which are incorporated into and constitute a part of this specification, illustrate one or more embodiments of the present invention and, together with the detailed description, serve to explain the principles and implementations of the invention. The figures are not to scale.

In the drawings:

FIG. 1 shows an apparatus which is suitable for carrying out the thermocompression bonding method in accordance with the invention and a snapshot of the thermocompression bonding method in accordance with the invention;

FIGS. 2-4 show further snapshots of the thermocompression bonding method in accordance with the invention;

FIG. 5 shows a wiring diagram, and

FIGS. 6, 7 show an alternative apparatus and snapshots of a thermocompression bonding method modified for an elastic apparatus.

### DETAILED DESCRIPTION OF THE INVENTION

The thermocompression bonding method is an established method for mounting semiconductor chips which are connected to a substrate via a few to very many soldered connections in form of soldering points. The substrate can also be a wafer. The substrate can further be a semiconductor chip which has already been mounted on another substrate. The semiconductor chip is pressed against the substrate and heated until the solder melts and the soldering points fuse and connect the semiconductor chip and the substrate with each other. The semiconductor chip is then cooled, so that the soldering points will solidify and become solid soldered connections.

The drawings are not shown true to scale for reasons of clarity of the illustrations, and especially the soldering points and a distance D are shown on an enlarged scale.

The thermocompression bonding method in accordance with the invention will be explained below in detail by reference to the mounting of semiconductor chips. The thermocompression bonding method in accordance with the invention can also be used for mounting other components. Only the parts of an automatic semiconductor assembly machine that are directly necessary for understanding the invention are shown.

### Embodiment 1

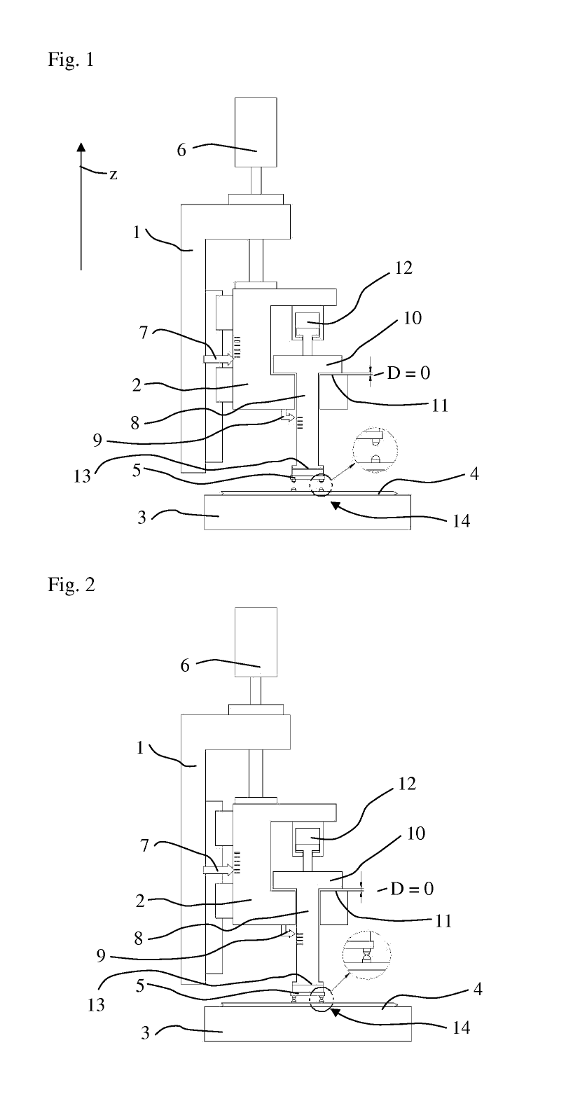

A semiconductor mounting apparatus comprises a pick and place system which receives one semiconductor chip after the other and places the same on a substrate. The pick and place system comprises a thermocompression bonding head (TC bonding head). FIG. 1 schematically shows the pick and place system 1 with the TC bonding head 2 and a substrate 4 which is provided on a support 3 and on which a semiconductor chip 5 is to be mounted which is accommodated by the TC bonding head 2. The TC bonding head 2 is displaceably mounted on the pick and place system 1 in a direction which extends perpendicularly to the surface of the substrate 4, which is usually the vertical direction and is designated in this case as the Z direction. A drive 6 which is fixed to the pick and place system 1 is used to move the TC bonding head 2 up and down in the Z direction. A first position measuring element 7 is used to detect the Z position of the TC bonding head 2. This position-controlled drive axis, which enables the displacement of the TC bonding head 2 relative to the pick and place system 1 in the Z direction, will be referred to below as the Z axis. The TC bonding head 2 is configured as follows for carrying out the thermocompression bonding method in accordance with the invention. The TC bonding head 2 comprises a chip gripper 8 with an extension 10 and a suction area which can be supplied with a vacuum in order to produce a suction force in the suction area for sucking up the semiconductor chip 5. The chip gripper 8 is displaceably mounted in the Z direction on the TC bonding head 2. The bearing is an air cushion bearing for example. The TC bonding head 2 further comprises a stop 11 and a force transmitter 12 which presses the extension 10 of the chip gripper 8 against the stop 11. The force transmitter 12 is a pneumatic, hydraulic or electromechanical force transmitter such as a voice coil, but it can also be a pretensioned spring. When the extension 10 of the chip gripper 8 rests on the stop 11, the chip gripper 8 is in the idle position relative to the TC bonding head 2. The deflection of the chip gripper 8 from said idle position is defined by the distance between the stop 11 and the extension 10, which will be referred to below as the distance D. A second position measuring element 9 is used to detect this distance D. The point in time at which the semiconductor chip 5 held by the chip gripper 8 touches the substrate 4 is known as touchdown. The touchdown is detected by means of the second position measuring element 9, but could also be determined by means of a separate touchdown detector. The chip gripper 8 contains a heater 13 in order to heat up the semiconductor chip 5, and it also advantageously contains a cooling system in order to actively cool the semiconductor chip 5, and an integrated temperature sensor. An advantageous embodiment of such a chip gripper 8 with a gap cooling has been described in the published Swiss patent application CH 706512 A1. The cooling system can also comprise cooling channels (not shown) integrated in the chip gripper 8, which are supplied with a cooling fluid such as compressed air for cooling.

The first position measuring element 7 is arranged on the pick and place system 1 and the second position measuring element 9 is arranged on the TC bonding head 2. The soldering points consisting of the solder are designated with reference numeral 14.

The thermocompression bonding method in accordance with the invention for mounting a semiconductor chip comprises the following steps:
Picking up the semiconductor chip 5 with the chip gripper 8.
Positioning the chip gripper 8 above an assigned substrate location of the substrate 4.

The pick and place system 1 moves the TC bonding head 2 to a position and the TC bonding head 2 rotates the chip gripper 8 about its longitudinal axis if necessary, so that the chip gripper 8 is positioned in a positionally precise way and with the correct orientation above the assigned substrate location. The force transmitter 12 is set in such a way that it presses the extension 10 of the chip gripper 8 with a predetermined force against the stop 11 of the TC bonding head 2, so that the chip gripper 8 is situated relative to the TC bonding head 2 in the idle position with D=0. This force is typically comparatively low, and amounts to a few newtons for example.
Lowering of the TC bonding head 2 to a Z position in which the chip gripper 8 is deflected relative to the TC bonding head 2 by a predetermined distance D_{S}.
The distance D_{S} is dependent on the process. It typically corresponds to the distance by which the soldering points 14 are reduced in size during the melting of the solder. D_{S} is therefore also known as bump collapse distance.
Once the semiconductor chip 5 touches the substrate 4, only the TC bonding head 2 will move downwardly while the chip gripper 8 stops. The TC bonding head 2 is therefore lowered to such an extent until the chip gripper 8 is deflected relative to the TC bonding head 2 by the predetermined distance D_{S}, i.e. until the distance D has reached the value D=D_{S}. This step can be performed in various variants such as:

### Variant 1

Lowering of the TC bonding head 2 and simultaneous monitoring of the distance D. The distance D begins to increase at the point in time at which the semiconductor chip 5 impacts on the substrate 4. This is known in the field as touchdown. The monitoring of the distance D occurs by means of the second position measuring element 9.
Detection of the Z position of the TC bonding head 2 as soon as it is determined that the distance D increases.
This Z position is designated as position Z₁. The position Z₁ corresponds to the Z position of the TC bonding head 2 at the point in time at which the touchdown was detected. This point in time is directly after the point in time (i.e. a few microseconds) at which the touchdown effectively occurred.
Stopping the lowering of the TC bonding head 2 when the TC bonding head 2 has reached a Z position Z₂=Z₁−D_{S}.
This is monitored by means of the position measuring element 7.
Closed-loop control of the Z position of the TC bonding head 2 to the value Z₂.

### Variant 2

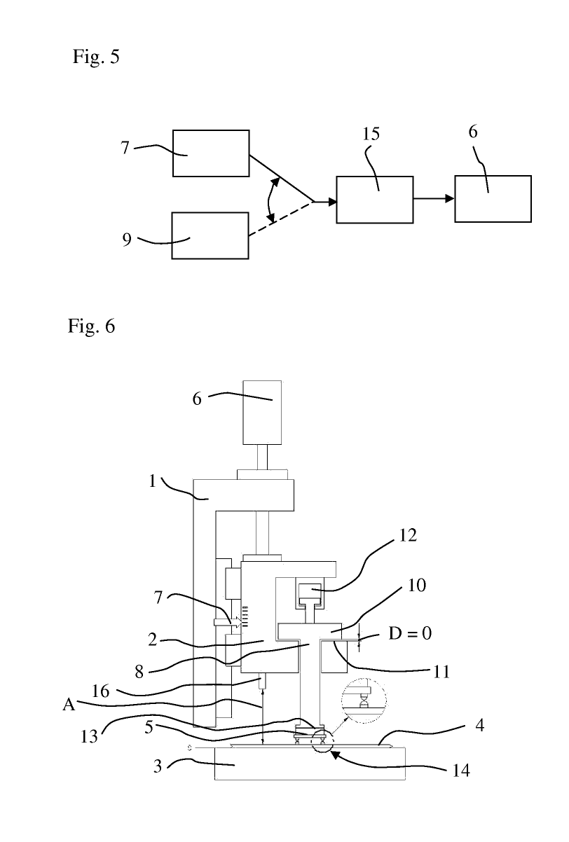

Lowering of the TC bonding head 2 and simultaneous monitoring of the distance D.
Stopping the lowering of the TC bonding head 2 when the second position measuring element 9 indicates that the distance D between the stop 11 and the extension 10 has reached the predetermined value D=D_{S}.
Optionally, usage of the second position measuring element 9 for the closed-loop control of the Z position of the TC bonding head 2 in such a way that the distance D=D_{S} is maintained until the temperature of the chip gripper 8 as measured by the temperature sensor reaches a predetermined value T₃ which still lies beneath the melting temperature of the solder, and reading of the value indicated by the first position measuring element 7 which corresponds to the current Z position of the TC bonding head 2, and from now usage of the first position measuring element 7 for the closed-loop control of the Z position of the TC bonding head 2 to the value that was just read.
FIG. 5 illustrates on the basis of a circuit diagram how either the position signal of the first position measuring element 7 or the position signal of the second position measuring element 9 is supplied for this purpose to a closed-loop control device 15 for controlling the drive 6, with which the Z position of the TC bonding head 2 is controlled.

The force produced by the force transmitter 12 now presses the semiconductor chip 5 against the substrate 4 with a relatively low force which is known as contact force and also includes the deadweight of the chip gripper 8.

The force generated by the force transmitter 12 is increased if necessary, so that the chip gripper 8 presses the semiconductor chip 5 with a higher force which is known as bonding force against the substrate 4. The bonding force ensures that any difference in height of the bumps of the semiconductor chip 5 is compensated by bump coining

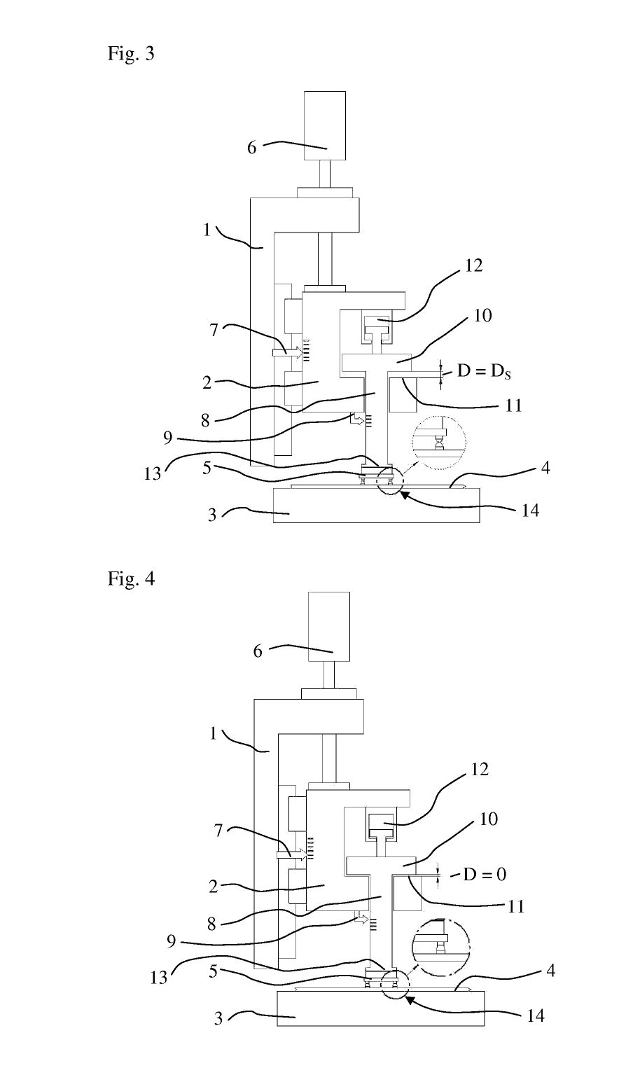

FIG. 1 shows a snapshot during the lowering of the TC bonding head 2 before the touchdown has occurred. FIG. 2 shows a snapshot at the time of the touchdown. FIG. 3 shows a snapshot when reaching the Z position Z₂ and the distance D_{S}.
Heater 13 is switched on in order to heat up the semiconductor chip 5.

The semiconductor chip 5 is heated. The force transmitter 12 presses the chip gripper 8 and therefore the semiconductor chip 5 with the contact force and optionally the bonding force against the substrate 4.
Optionally, deactivation of the force transmitter 12 or at least reduction of the force of the force transmitter 12 before the temperature of the semiconductor chip 5 reaches the melting temperature of the solder. At least a residual force remains, with which the chip gripper 8 presses the semiconductor chip 5 against the substrate 4. The residual force is equal to the original contact force for example.

Reaching the melting temperature of the solder is now directly imminent, i.e. it will occur within a few milliseconds. The Z position of the TC bonding head 2 is set in such a way that the chip gripper 8 and, together with the same, the semiconductor chip 5 will be lowered by the distance D_{S} during the collapse occurring upon reaching and exceeding the melting temperature of the solder.

As soon as the temperature of the semiconductor chip 5 has reached the melting temperature of the solder, the soldering points 14 will begin to deform as a result of the pressure produced by the force transmitter 12 and transmitted by the chip gripper 8 onto the soldering points 14.

The chip gripper 8 therefore moves down relative to the TC bonding head 2 until the extension 10 of the chip gripper 8 rests on the stop 11 of the TC bonding head 2 again, i.e. until the distance D=0 has been reached. From now on the chip gripper 8 no longer exerts any force on the substrate 4, so that the force transmitter 12 can be deactivated, unless this has not yet already occurred at an earlier point in time.

FIG. 4 shows a snapshot at the point in time at which the distance D=0 has been reached.
Deactivation of the heater 13 once a first predetermined condition has been fulfilled, which ensures that the temperature of the semiconductor chip 5 has reached a value above the melting temperature of the solder.

The first predetermined condition is for example that the temperature of the chip gripper 8 has reached a predetermined value T₁ which lies above the melting temperature of the solder. The first predetermined condition can be alternatively that a predetermined period of time has passed since the activation of the heater 13. This duration will be set for such a time that the temperature of the chip gripper 8 has securely reached a value which lies above the melting temperature of the solder. Since the TC bonding head 2 is held on the Z position Z₂ and the extension 10 of the chip gripper 8 rests on the stop 11 of the TC bonding head 2, the soldering points 14 are not compressed.
Waiting until the temperature of the chip gripper 8 has fallen beneath the melting temperature of the solder.
The duration of this step is preferably reduced by active cooling of the chip gripper 8, e.g. by:
Activating the cooling system of the chip gripper 8.
Cooling occurs until the soldering points 14 are sufficiently solid.
Deactivation of the cooling system of the chip gripper 8 once a second predetermined condition has been fulfilled which ensures that the temperature of the semiconductor chip 5 has decreased to a value below the melting temperature of the solder. The second predetermined condition is for example that the temperature of the chip gripper 8 has fallen to a predetermined value T₂ which lies beneath the melting temperature of the solder. The second predetermined condition can be alternative in that a predetermined period of time has passed since the activation of the cooling. The period of time will be set to such a length that the temperature of the chip gripper 8 securely reaches a value which lies beneath the melting temperature of the solder.
Lifting of the TC bonding head 2.

The TC bonding head 2 is lifted and moved away by the pick and place system 1 in order to collect the next semiconductor chip.

If the stiffness of the pick and place system 1 is sufficiently large that the contact force exerted on the substrate 4 is unable to downwardly press the substrate support 3, the mounting method can be performed as described above. However, if the stiffness of the pick and place system 1 is insufficient so that the contact force exerted on the substrate 4 will downwardly displace the substrate support 3 relative to the TC bonding head 2 and will therefore deflect the substrate 4 relative to the TC bonding head 2 from a zero position, the apparatus and the method as described above will be modified, namely according to the following embodiments 2 and 3.

### Embodiment 2

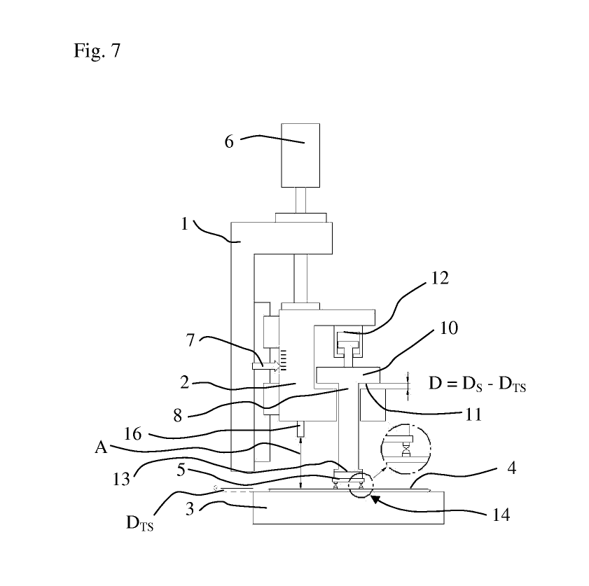

In the apparatus, the second position measuring element 9 is replaced by a distance sensor 16, which is attached to the TC bonding head 2 and measures a distance A between the distance sensor 16 and the support 3 or the surface of the substrate 4. FIG. 6 shows the modified apparatus at the point in time at which the semiconductor chip 5 touches the substrate 4. The support 3 is in its idle position relative to the Z axis of the pick and place system 1 or the TC bonding head 2. FIG. 7 shows the modified apparatus at the point in time at which the lowering of the TC bonding head 2 is completed. The support 3 is lowered by a value D_{TS} relative to the TC bonding head 2 due to the elasticity of the overall system and the chip gripper 8 is lifted relative to the TC bonding head 2 by a value D_{S}−D_{TS}.

The lowering of the TC bonding head 2 in an apparatus in which the forces occurring during thermocompression bonding cause elastic deformations can be subdivided into three successive phases, i.e. a first phase in which the distance A decreases continuously, a second phase in which the distance A remains constant, and a third phase in which the distance A decreases again.

In the first phase the semiconductor chip 5 does not yet touch the substrate 4. The distance A therefore decreases continuously during the lowering of the TC bonding head 2.

The second phase starts once the semiconductor chip 5 touches the substrate 4. The force produced by the force transmitter 12 (the aforementioned contact force) presses the semiconductor chip 5 against the substrate 4 and causes a deformation of the elastic overall system with the consequence that the support 3 for the substrate 4 is pressed downwardly relative to the Z axis of the pick and place system 1 and/or the TC bonding head 2 is pressed upwardly relative to the Z axis of the pick and place system 1 and/or the pick and place system 1 will bend. In summary, a relative displacement of the support 3 is obtained relative to the TC bonding head 2 by a distance D_{TS}. The deformation of the entire system produces a force which is directed against the contact force. As long as this force is lower than the contact force, the force transmitter 12 presses the extension 10 of the chip gripper 8 against the stop of the TC bonding head 2. The chip gripper 8 therefore moves downwardly together with the TC bonding head 2, presses against the support 3 and therefore displaces the support 3 and the TC bonding head 2 relative to one another by the distance D_{TS} from its normal distance. Normal distance or normal position means the distance between the support 3 and the TC bonding head 2 or its position in the case of lack of action of force of the chip gripper 8. Once this force is as large as the contact force, the deformation of the entire system terminates, i.e. the support 3 remains in situ. The second phase is finished. The distance A remains constant in the second phase.

The third phase starts in which the contact force and the aforementioned force are equally large. The lowering of the TC bonding head 2 continues. Since the support 3 is not deflected further downwardly, the distance A decreases again, but now the chip gripper 8 is displaced relative to the TC bonding head 2. The third phase and therefore the lowering of the TC bonding head 2 is terminated once the chip gripper 8 is deflected relative to the TC bonding head 2 by the distance D=D_{S}−D_{TS}.

The step of the lowering of the TC bonding head 2 is performed in the modified method according to these three phases as follows:
Lowering of the TC bonding head 2 up to a Z position in which the chip gripper 8 is deflected relative to the TC bonding head 2 by the distance D=D_{S}−D_{TS}, wherein the distance D_{S} is predetermined and the distance D_{TS} is determined during the step.

The distance D_{TS} is determined during the lowering of the TC bonding head 2 by
monitoring the distance A and reading a first Z value z₁₁, which is supplied by the first position measuring element 7 at the point in time from which the distance A no longer decreases and remains constant for a while, and reading a second Z value z₁₂, which is supplied by the first position measuring element 7 at the point in time from which the distance A decreases again, and calculating the distance D_{TS}=z₁₁−z₁₂.

The result is that at the end of the third phase the TC bonding head 2 has reached the position

z=z₁₁−D_{S}−D_{TS}, while the support 3 and the TC bonding head 2 have been displaced relative to each other with respect to the normal distance by the value D_{TS}.

When the semiconductor chip 5 has reached and exceeded the melting temperature of the solder during heating up, the solder will melt, the soldering points 14 will collapse and the contact force will disappear. As a result, the entire system moves by the distance D_{TS} to its normal position and the chip gripper 8 moves down by the distance D_{S}−D_{TS} to its idle position in which the extension 10 rests on the stop of the TC bonding head 2. The soldering points 14 are therefore compressed by the distance D_{S}.

The method is further modified in those cases where D_{TS}>D_{S}. The apparatus is the same as in the embodiment 2.

### Embodiment 3

The step of lowering the TC bonding head 2 is carried out as in the embodiment 2, but with the modification that the TC bonding head 2 is lowered to a Z position in which the chip gripper 8 is deflected relative to the TC bonding head 2 by the distance D=D_{S}. The distance D_{TS} is determined during the lowering as in the embodiment 2, which indicates the extent to which the support 3 has been lowered in relation to the Z axis of the pick and place system 1.

Once the lowering of the TC bonding head 2 has ended, the Z value of the position measuring element 7 is read and stored as value Z₃₁. The distance A remains constant until the melting of the solder. Once the melting of the solder commences, the contact force disappears and the entire system moves to its normal position, i.e. the distance A begins to decrease from this point in time.

The point in time at which the melting of the solder occurs is detected by means of the distance sensor 16 as decrease of the distance A and subsequently the lifting of the TC bonding head 2 by the distance D_{TS} to the Z height Z=Z₃₁+D_{TS} is initiated. Alternatively, the TC bonding head 2 is lifted by the distance D_{TS} to the Z height Z=Z₁+D_{TS} immediately before, during or after the point in time at which the semiconductor chip 5 has reached the melting temperature of the solder during heating up. The precise point in time depends on the properties of the process. In order to ensure that the lifting of the TC bonding head 2 can occur in a sufficiently rapid manner, the drive 6 must be a highly dynamic drive, e.g. a linear motor or a voice coil drive.

The invention offers several advantages:
Only one position-controlled drive axis is necessary in order to lower the semiconductor chip to the substrate location, namely the Z axis of the TC bonding head 2.
The detection of the touchdown and the only passive movement of the chip gripper 8 from the idle position with D=0 to a deflected position with D=D_{S} or D=D_{S}−D_{TS} (because the TC bonding head 2 is lowered slightly further after reaching the touchdown point) and again to the idle position with D=0 (because the soldering points 14 become soft and deform under the pressure of the chip gripper 8) leads to a highly precise constancy in the height of the soldering points 14 within narrow tolerances.
The construction is simple with respect to its mechanics and control technology.
The optional step of using the second position measuring element 9 for the closed-loop control of the Z position of the TC bonding head 2 in such a way that the distance D=D_{S} is maintained until shortly before reaching the melting temperature of the solder ensures that thermal expansions of the chip gripper 8 occurring during the heating of the semiconductor chip 5 will not have an influence on the distance D and will also ensure that the extension 10 of the chip gripper 8 will not rest inadvertently on the stop 11 of the TC bonding head 2.
The method or the modified method is suitable both for apparatuses of high stiffness which do not deform by the contact force, but also for apparatuses which elastically deform under the influence of the contact force.

1. Thermocompression bonding method for mounting semiconductor chips on a surface of a substrate, in which one semiconductor chip after the other is taken up by a chip gripper and is mounted on the substrate, wherein a TC bonding head is displaceable by means of a drive in a Z direction extending perpendicularly to the surface of the substrate, the chip gripper is displaceably mounted on the TC bonding head in the Z direction, and a force transmitter fixed to the TC bonding head is configured to press an extension of the chip gripper in the direction of a stop of the TC bonding head, and wherein the chip gripper comprises a heater, wherein the following steps are performed in order to produce solid soldered connections in form of soldering points between a semiconductor chip and the substrate:
picking up the semiconductor chip with the chip gripper;
positioning of the chip gripper above the assigned substrate location;
lowering the TC bonding head by means of the drive to a Z position in which the chip gripper is deflected by a predetermined distance DS relative to the TC bonding head, so that the extension of the chip gripper does not rest on the stop of the TC bonding head;
heating up of the semiconductor chip by means of the heater;
terminating the heat-up of the semiconductor chip once the semiconductor chip has reached a temperature above the melting temperature of the solder of the soldering points, so that the soldering points melt and the extension of the chip gripper comes to lie on the stop of the TC bonding head;
waiting until the temperature of the semiconductor chip has fallen to a value beneath the melting temperature of the solder, and
lifting of the TC bonding head.

2. Thermocompression bonding method according to claim 1, further comprising actively cooling of the chip gripper during said waiting.

3. Thermocompression bonding method according to claim 1, further comprising:
from the start of the heating-up of the semiconductor chip until the point in time at which the temperature of the chip gripper has reached a predetermined value that lies beneath the melting temperature of the solder measuring the actual deflection D of the chip gripper relative to the TC bonding head and using the measured deflection D for a closed-loop control of the Z position of the TC bonding head in such a way that the chip gripper remains deflected by the predetermined distance D_{S}.

4. Thermocompression bonding method according to claim 2, further comprising:
from the start of the heating-up of the semiconductor chip until the point in time at which the temperature of the chip gripper has reached a predetermined value that lies beneath the melting temperature of the solder measuring the actual deflection D of the chip gripper relative to the TC bonding head and using the measured deflection D for a closed-loop control of the Z position of the TC bonding head in such a way that the chip gripper remains deflected by the predetermined distance D_{S}.

5. Thermocompression bonding method according to claim 1, wherein the step of lowering of the TC bonding head comprises:
determining a distance D_{TS} by which a support, on which the substrate rests, and the TC bonding head are displaced relative to each other by the force exerted by the chip gripper, and reducing the distance D_{S} by the distance D_{TS}.

6. Thermocompression bonding method according to claim 2, wherein the step of lowering of the TC bonding head comprises:
determining a distance D_{TS} by which a support, on which the substrate rests, and the TC bonding head are displaced relative to each other by the force exerted by the chip gripper, and reducing the distance D_{S} by the distance D_{TS}.

7. Thermocompression bonding method according to claim 3, wherein the step of lowering of the TC bonding head comprises:
determining a distance D_{TS} by which a support, on which the substrate rests, and the TC bonding head are displaced relative to each other by the force exerted by the chip gripper, and reducing the distance D_{S} by the distance D_{TS}.

8. Thermocompression bonding method according to claim 4, wherein the step of lowering of the TC bonding head comprises:
determining a distance D_{TS} by which a support, on which the substrate rests, and the TC bonding head are displaced relative to each other by the force exerted by the chip gripper, and reducing the distance D_{S} by the distance D_{TS}.

9. Thermocompression bonding method according to claim 1, wherein the step of lowering of the TC bonding head comprises:
determining a distance D_{TS} by which a support, on which the substrate rests, and the TC bonding head are displaced relative to each other by the force exerted by the chip gripper, and lifting of the TC bonding head by the distance D_{TS} as soon as the solder starts melting.

10. Thermocompression bonding method according to claim 2, wherein the step of lowering of the TC bonding head comprises:
determining a distance D_{TS} by which a support, on which the substrate rests, and the TC bonding head are displaced relative to each other by the force exerted by the chip gripper, and lifting of the TC bonding head by the distance D_{TS} as soon as the solder starts melting.

11. Thermocompression bonding method according to claim 3, wherein the step of lowering of the TC bonding head comprises:
determining a distance D_{TS} by which a support, on which the substrate rests, and the TC bonding head are displaced relative to each other by the force exerted by the chip gripper, and lifting of the TC bonding head by the distance D_{TS} as soon as the solder starts melting.

12. Thermocompression bonding method according to claim 4, wherein the step of lowering of the TC bonding head comprises:
determining a distance D_{TS} by which a support, on which the substrate rests, and the TC bonding head are displaced relative to each other by the force exerted by the chip gripper, and lifting of the TC bonding head by the distance D_{TS} as soon as the solder starts melting.

13. Apparatus for mounting semiconductor chips on a surface of a substrate, the apparatus comprising:
a TC bonding head which is displaceably mounted in a Z direction extending perpendicularly to the surface of the substrate and comprises a stop;
a chip gripper which is displaceably mounted in the Z direction on the TC bonding head and which comprises an extension;
a force transmitter which is fixed to the TC bonding head and which presses the extension of the chip gripper in the Z direction against the stop of the TC bonding head;
a drive for moving the TC bonding head in the Z direction;
a first position measuring element for the detection of the Z position of the TC bonding head;
a second position measuring element for detecting a deflection of the chip gripper relative to the TC bonding head; and
a closed-loop control device for controlling the drive, wherein the control device is set up to control the drive selectively on the basis of a position signal which is supplied by the first position measuring element or the second position measuring element.
